(19) United States
(12) Patent Application Publication
(10) Pub. No.: US 2023/0366075 A1
(43) Pub. Date: Nov. 16, 2023

(54) DEPOSITION APPARATUS INCLUDING MASK ASSEMBLY AND METHOD FOR MANUFACTURING MASK ASSEMBLY

(71) Applicant: Samsung Display Co., Ltd., Yongin-si (KR)

(72) Inventors: JEONGKUK KIM, Yongin-si (KR); YOUNGMIN MOON, Yongin-si (KR); SEUNGYONG SONG, Yongin-si (KR); KYU HWAN HWANG, Yongin-si (KR)

(73) Assignee: Samsung Display Co., Ltd., Yongin-si (KR)

(21) Appl. No.: 18/298,539

(22) Filed: Apr. 11, 2023

(30) Foreign Application Priority Data
May 16, 2022 (KR) 10-2022-0059657

(51) Int. Cl. C23C 14/04

(52) U.S. Cl. CPC C23C 14/042; H10K 71/166

(57) ABSTRACT

A mask assembly including a frame including a frame opening, an open sheet physically connected to the frame including sheet openings corresponding to the frame opening, and hole groups each of which includes adsorption holes spaced apart from a corresponding sheet opening among the sheet openings, and masks each of which includes deposition openings, and is physically connected to the open sheet so as to be aligned with a corresponding sheet opening among the sheet openings. Each of the masks may overlap the adsorption holes of a corresponding hole group among the hole groups.

### CROSS-REFERENCE TO RELATED APPLICATION(S)

This U.S. non-provisional patent application claims priority to and benefits of Korean Patent Application No. 10-2022-0059657 under 35 U.S.C. § 119, filed on May 26, 2022 in the Korean Intellectual Property Office (KIPO), the entire contents of which are incorporated herein by reference.

### BACKGROUND

### 1. Technical Field

The disclosure herein relates to a deposition apparatus including a mask assembly having a structure with improved deposition precision, and a method for manufacturing the mask assembly.

### 2. Description of the Related Art

A display panel includes pixels. Each of the pixels may include a driving element such as a transistor and a display element such as an organic light emitting element. The display element may be formed by depositing an electrode and various functional layers on a substrate.

The functional layers constituting the display element may be patterned and provided using a mask having penetrated deposition openings. At this time, shapes of the patterned functional layers may be controlled according to the shape of an open region of the mask and the like. Accordingly, in order to improve the deposition quality of the patterned functional layers, there is a need for technology development in regard to a mask in which deposition openings are processed with high precision and a method for manufacturing the mask.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a mask assembly for improving the deposition quality of functional layers formed on a target substrate, and a deposition apparatus including the same.

The disclosure also provides a simplified processing facility required for a method for manufacturing a mask assembly.

An embodiment of the disclosure provides a mask assembly that may include a frame including a frame opening, an open sheet physically connected to the frame and including sheet openings corresponding to the frame opening, and hole groups each of which includes adsorption holes spaced apart from a corresponding sheet opening among the sheet openings, and masks each of which includes deposition openings, and is physically connected to the open sheet so as to be aligned with a corresponding sheet opening among the sheet openings. Each of the masks may overlap the adsorption holes of a corresponding hole group among the hole groups.

In an embodiment, each of the masks may include a first region in which the deposition openings may be defined, and a second region protruding from the first region in plan view and overlapping the adsorption holes of a corresponding hole group. The mask assembly may further include welding protrusions disposed on an upper surface of the second region of each of the masks.

In an embodiment, in plan view, the adsorption holes may be more adjacent to a corresponding sheet opening among the sheet openings than the welding protrusions.

In an embodiment, the first region of each of the masks may include short sides each of which is extended in a first direction and spaced apart in a second direction intersecting the first direction, and long sides each of which is extended in the second direction, spaced apart in the first direction, and extended to the short sides. The second region of each of the masks may include first portions protruding from the short sides and second portions protruding from the long sides.

In an embodiment, among the adsorption holes, a number of adsorption holes overlapping each of the first portions and a number of adsorption holes overlapping each of the second portions may be different from each other.

In an embodiment, each of the adsorption holes may have a shape of at least one of a circle, an oval, and a quadrangle, among the adsorption holes, adsorption holes overlapping the first portions may be arranged in the first direction, and among the adsorption holes, adsorption holes overlapping the second portions may be arranged in the second direction.

In an embodiment, among the adsorption holes, each of adsorption holes overlapping the first portions may be extended in the first direction and arranged in the first direction, and among the adsorption holes, each of adsorption holes overlapping the second portions may be extended in the second direction and arranged in the first direction.

In an embodiment, the open sheet may include an upper surface facing the masks, a lower surface opposing the upper surface, and an inner surface extended between the upper surface and the lower surface and defining the adsorption holes. An angle between the upper surface and the inner surface and the angle between the lower surface and the inner surface may be right angles.

In an embodiment, the open sheet may include an upper surface facing the masks, a lower surface opposing the upper surface, and an inner surface extending between the upper surface and the lower surface and defining the adsorption holes. An angle between the upper surface and the inner surface or the angle between the lower surface and the inner surface may be obtuse angles.

In an embodiment, a width of each of the adsorption holes may be about 50 um to about 300 um.

In an embodiment, the mask assembly may further include welding protrusions overlapping the frame and disposed on an upper surface of the open sheet.

In an embodiment, at least one of the frame, the open sheet, and the masks may include invar.

In an embodiment, a thickness of the open sheet may be about 50 um to about 300 um, and a thickness of each of the masks may be about 10 um to about 50 um.

In an embodiment of the disclosure, a deposition apparatus may include a chamber, a mask assembly disposed inside the chamber and including a deposition substrate, and a deposition source spraying a deposition material toward the mask assembly. The mask assembly may include a frame having a frame opening, an open sheet physically connected to the frame and including sheet openings corresponding to the frame opening, and hole groups each of which includes adsorption holes spaced apart from a corresponding sheet opening among the sheet openings, and masks each of which includes deposition openings and is physically connected to the open sheet so as to be aligned with a corresponding sheet opening among the sheet openings. Each of the masks may overlap the adsorption holes of a corresponding hole group among the hole groups.

In an embodiment of the disclosure, a method for manufacturing a mask assembly may include coupling an open sheet on which a sheet opening and adsorption holes spaced apart from the sheet opening are formed to a frame, disposing the open sheet on a work jig in which first vacuum holes and second vacuum holes spaced apart from the first vacuum holes are defined such that the adsorption holes and the second vacuum holes are aligned, forming a descending airflow in the first vacuum holes to bring the open sheet in close physical contact with the work jig, disposing a mask in which deposition openings corresponding to the sheet opening are defined on the open sheet, forming a descending airflow in the adsorption holes and the second vacuum holes to bring the mask in close physical contact with the open sheet, and coupling the mask to the open sheet.

In an embodiment, the mask may include a first region in which the deposition openings are defined, a second region protruding from the first region, and a third region protruding from the second region, wherein the second region includes a margin region, a welding region, and a trimming region arranged in an order adjacent to the deposition openings and overlapping the adsorption holes. The method may further include stretching the third region to align the sheet opening and the deposition openings.

In an embodiment, the stretching of the third region to align the sheet opening and the deposition openings and the disposing of a mask on the open sheet may be simultaneously performed.

In an embodiment, the coupling of the mask to the open sheet may be performed by a welding process to the welding region.

In an embodiment, the method may further include, after the coupling of the mask to the open sheet, removing the trimming region and the third region by irradiating a laser beam to the trimming region.

In an embodiment, a width of the adsorption holes in a direction may be smaller than a width of the second vacuum holes in the direction.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic cross-sectional view of a deposition apparatus according to an embodiment of the disclosure;

FIG. 2 is a schematic plan view of a mask assembly according to an embodiment of the disclosure;

FIG. 3 is an exploded schematic perspective view of a mask assembly according to an embodiment of the disclosure;

FIG. 4 is a schematic plan view of an open sheet according to an embodiment of the disclosure;

FIG. 5A is a schematic plan view of a method for manufacturing a mask assembly according to an embodiment of the disclosure;

FIG. 5B is a schematic cross-sectional view of a method for manufacturing a mask assembly according to an embodiment of the disclosure;

FIG. 5C is a schematic plan view of a method for manufacturing a mask assembly according to an embodiment of the disclosure;

FIG. 5D is a schematic cross-sectional view of a method for manufacturing a mask assembly according to an embodiment of the disclosure;

FIG. 5E is a schematic cross-sectional view of a method for manufacturing a mask assembly according to an embodiment of the disclosure;

FIG. 5F is a schematic cross-sectional view of a method for manufacturing a mask assembly according to an embodiment of the disclosure;

FIG. 5G is a schematic cross-sectional view of a method for manufacturing a mask assembly according to an embodiment of the disclosure;

FIG. 6 is a schematic cross-sectional view of an open sheet according to an embodiment of the disclosure;

FIG. 7 is a schematic cross-sectional view of an open sheet according to an embodiment of the disclosure;

FIG. 8 is a schematic plan view of an open sheet according to an embodiment of the disclosure; and

FIG. 9 is a schematic cross-sectional view of a display panel according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the disclosure, when an element (or a region, a layer, a portion, and the like) is referred to as being “on,” “connected to,” or “coupled to” another element, it means that the element may be directly disposed on/connected to/coupled to the other element, or that a third element may be disposed therebetween.

It will be understood that the terms “connected to,” “coupled to,” “contact,” and the like, may include a physical and/or electrical connection or coupling.

Like reference numerals refer to like elements. Also, in the drawings, the thickness, the ratio, and the dimensions of elements may be exaggerated for an effective description of technical contents.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the disclosure.

In addition, terms such as “below,” “lower,” “above,” “upper,” and the like are used to describe the relationship of the components shown in the drawings. The terms are used as a relative concept and are described with reference to the direction indicated in the drawings.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It should be understood that the terms “comprise,” “include,” “have,” and the like, are intended to specify the presence of stated features, integers, steps, operations, elements, components, or combinations thereof in the disclosure, but do not preclude the presence or addition of one or more other features, integers, steps, operations, elements, components, or combinations thereof.

“About,” “approximately,” “substantially,” and the like, as used herein are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It is also to be understood that terms such as terms defined in commonly used dictionaries should be interpreted as having meanings consistent with the meanings in the context of the related art, and should not be interpreted in too ideal of a sense or an overly formal sense unless explicitly defined herein.

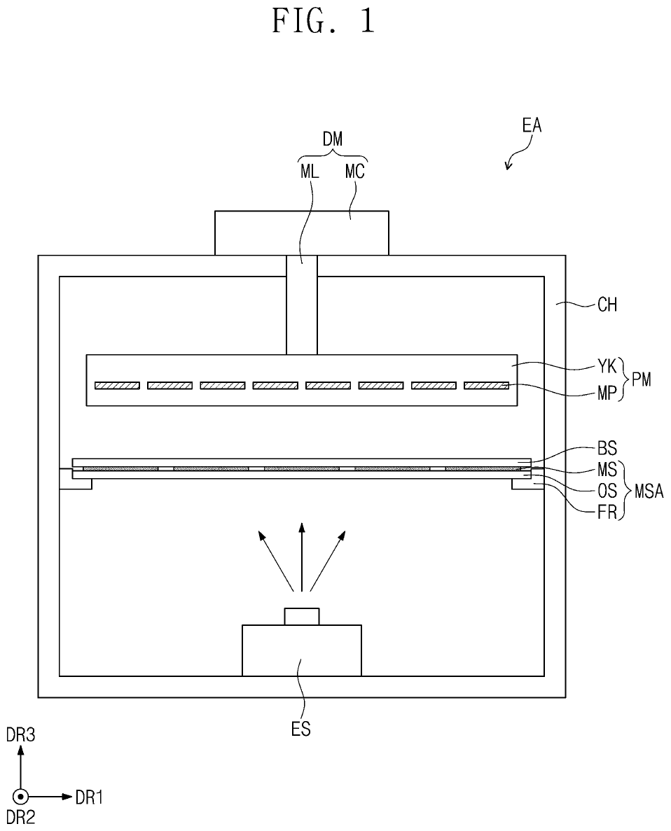

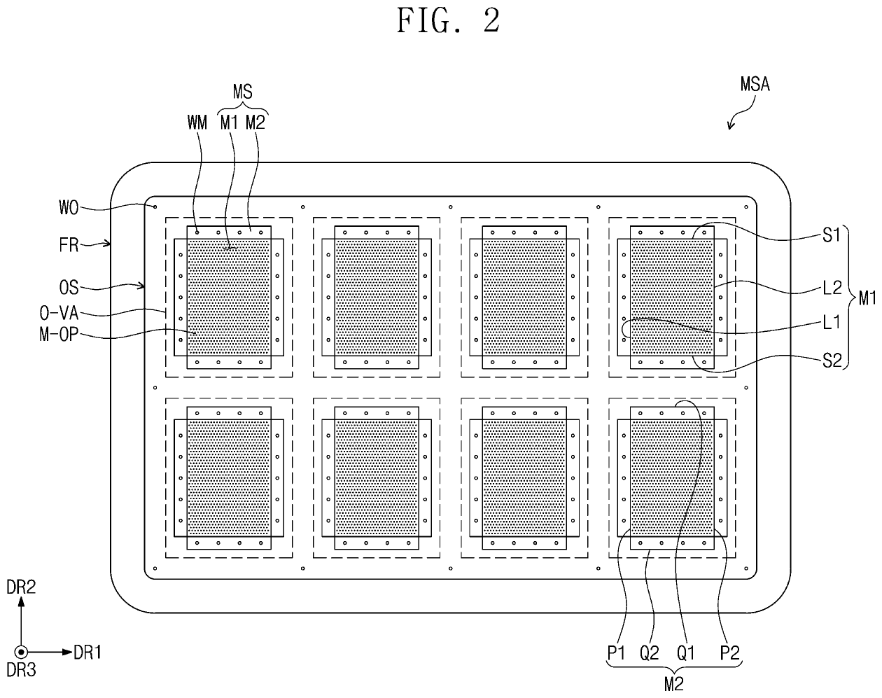

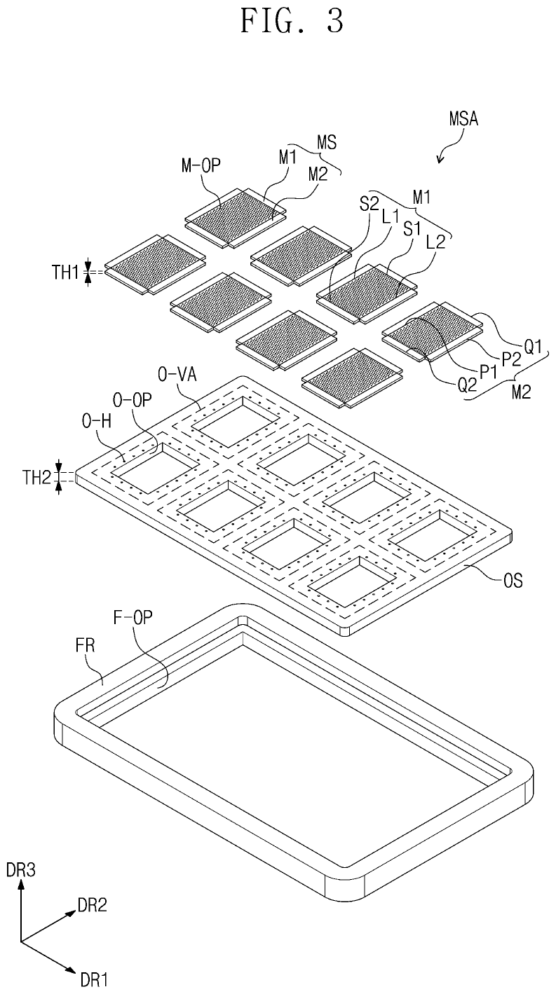

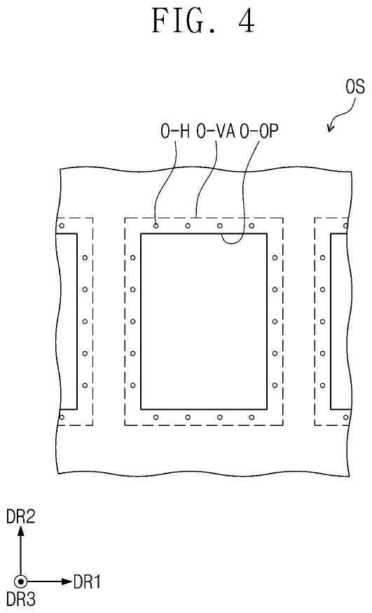

FIG. 1 is a schematic cross-sectional view of a deposition apparatus according to an embodiment of the disclosure. FIG. 2 is a schematic plan view of a mask assembly according to an embodiment of the disclosure. FIG. 3 is an exploded schematic perspective view of a mask assembly according to an embodiment of the disclosure. FIG. 4 is a schematic plan view of an open sheet according to an embodiment of the disclosure.

Referring to FIG. 1 to FIG. 3, a deposition apparatus EA according to the disclosure may include a chamber CH, a deposition source ES, a mask assembly MSA, a deposition substrate BS, a pressurizing part PM, and a transfer part DM. The deposition apparatus EA may be a device which deposits an organic material, a conductive material, and/or the like on the deposition substrate BS.

The chamber CH may provide an internal space in which a deposition process may be performed. The deposition source ES, the mask assembly MSA, the deposition substrate BS, the pressurizing part PM, and a transfer rod ML of the transport part DM may be disposed in the internal space of the chamber CH.

The deposition source ES may provide a deposition material to the deposition substrate BS. For example, the deposition source ES may evaporate the deposition material including an inorganic material, an organic material, and/or a material toward the mask assembly MSA. The deposition material may pass through the mask assembly MSA and be deposited on the deposition substrate BS. The deposition source ES may implement the deposition by a method of heating and evaporating the deposition material at a high temperature. According to an embodiment, the deposition apparatus EA may further include a transferer for moving the deposition source ES in a first direction DR1 and a second direction DR2 which may be horizontal directions.

The pressurizing part PM may include a magnetic plate MP and a support plate YK. According to an embodiment, the pressurizing part PM may further include a cooling plate disposed between the deposition substrate BS and the support plate YK.

The magnetic plate MP may be disposed inside the support plate YK. However, the disclosure is not limited thereto, and the position, shape, and quantity of the magnetic plate MP is not limited to any one embodiment as long as it is disposed on the mask assembly MSA and magnetically couples masks MS and the deposition substrate BS which are included in the mask assembly MSA.

The magnetic plate MP may attract the masks MS by forming a magnetic force while the deposition substrate BS and the mask assembly MSA are in close contact. Accordingly, the coupling force between the deposition substrate BS and the mask assembly MSA may be increased.

The magnetic plate MP may prevent a lift-off phenomenon which occurs due to a difference in curvature between the deposition substrate BS and the masks MS, thereby preventing a shadowing phenomenon, which is a deposition failure, from occurring. The magnetic plate MP may be provided as either a permanent magnet or an electromagnet.

The support plate YK may accommodate the magnetic plate MP. The support plate YK may be coupled to the transfer part DM to bring the magnetic plate MP in close contact with the deposition substrate BS or separate the magnetic plate MP from the deposition substrate BS.

The cooling plate may be disposed between the deposition substrate BS and the support plate YK. In order to prevent the deposition substrate BS or the masks MS from being overheated during a deposition process, the cooling plate may provide a function of cooling the deposition substrate BS and/or the masks MS. Accordingly, the deposition substrate BS may be prevented from being deformed. A cooling line through which cooling water or cooled air is injected may be provided inside the cooling plate.

The transfer part DM may be connected to the pressurizing part PM. The transfer part DM may include the transfer rod ML and a transfer body MC. The transfer body MC may transfer the pressurizing part PM in a third direction DR3, for example, in up/down directions, by way of the transfer rod ML.

For example, the transfer body MC may be disposed outside of the chamber CH. The transfer body MC may be implemented as either a cylinder or a motor. For example, in case that the transfer body MC is a cylinder, the transfer rod ML may be a piston. In case that the transfer body MC is a motor, the transfer rod ML may be implemented as a ball screw shaft which may be moved up/down according to the rotation of the motor. However, the disclosure is not limited thereto, and as long as the transfer part DM may move the pressurizing part PM, the device not limited to any one embodiment.

The mask assembly MSA may be disposed inside the chamber CH and may support the deposition substrate BS. The mask assembly MSA may include a frame FR, an open sheet OS, and masks MS. At least one among the frame FR, the open sheet OS, and the masks MS may include invar.

The frame FR may be disposed on a sidewall of the chamber CH to support the open sheet OS to which the masks MS may be coupled. The frame FR may include a frame opening F-OP. The shape, position, and number of the frame FR are not limited to any one embodiment as long as the frame FR may support the open sheet OS.

As illustrated in FIG. 2, the open sheet OS may be disposed on the frame FR and coupled to the frame FR, and the masks MS may be disposed on the open sheet OS and coupled to the open sheet OS. According to the disclosure, the coupling between the open sheet OS and the frame FR and the coupling between the masks MS and the open sheet OS may be achieved through a welding process. Accordingly, the mask assembly MSA may further include welding protrusions WM formed in conjunction with coupling the masks MS to the open sheet OS and welding protrusions WO formed in conjunction with coupling the open sheet OS to the frame FR. The positions and numbers of the welding protrusions WM and the welding protrusions WO are not limited to any one embodiment.

However, the achievement of the coupling between the open sheet OS and the frame FR and the coupling between the masks MS and the open sheet OS are not limited to a welding process, and may be achieved by a separate structure or adhesive. For example, there may not be welding protrusions.

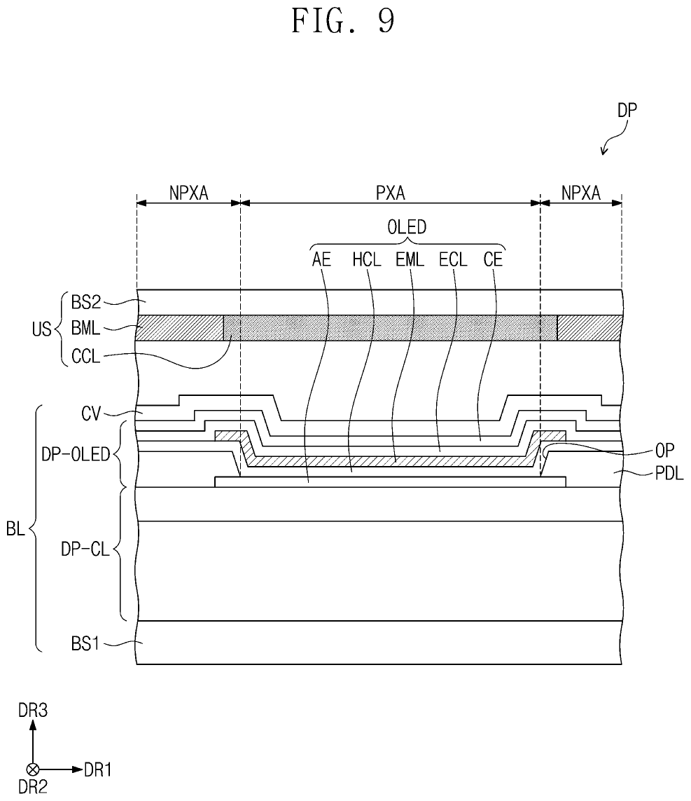

Each of the masks MS according to the disclosure may include a first region M1 including deposition openings M-OP and a second region M2 protruding from the first region Ml. During a deposition process, deposition materials passed through the deposition openings M-OP may be deposited on the deposition substrate BS and may constitute the light emitting layer EML (see FIG. 9) included in the display panel DP (see FIG. 9). The light emitting layer EML (see FIG. 9) may have a shape individually patterned for each light emitting region PXA (see FIG. 9).

The first region M1 may include short sides S1 and S2 each of which is extended in the first direction DR1 and which are spaced apart along (in) the second direction DR2 and long sides L1 and L2 each of which is extended in the second direction DR2, and which are spaced apart along the first direction DR1, and extended (connected) to the short sides S1 and S2.

The second region M2 may include first portions P1 and P2 which protrude in the first direction DR1 from corresponding short sides S1 and S2, and second portions Q1 and Q2 which protrude in the second direction DR2 from corresponding long sides L1 and L2.

According to an embodiment, each of the masks MS may have a thickness TH1 of approximately (about) 10 um to approximately 50 um.

As illustrated in FIG. 3, the open sheet OS may include multiple sheet openings O-OP and multiple adsorption holes O-H surrounding a corresponding sheet opening O-OP among the sheet openings O-OP. On the open sheet OS, one sheet opening O-OP and adsorption holes O-H surrounding the one sheet opening O-OP may be defined as one process region O-VA. One process region O-VA may be coupled with one mask MS. According to the disclosure, the sheet openings O-OP may correspond to one frame opening F-OP, and deposition openings M-OP included in each of the masks MS may correspond to one sheet opening O-OP.

In the disclosure, adsorption holes O-H surrounding a corresponding sheet opening O-OP among the sheet openings O-OP may be defined as a “hole group.” For example, according to an embodiment, eight sheet openings O-OP and eight hole groups corresponding thereto may be defined.

According to an embodiment, the open sheet OS may have a thickness TH2 of approximately 50 um to approximately 300 um.

FIG. 3 illustrates that process regions O-VA of 4 rows×2 columns are defined in the open sheet OS, but the disclosure is not limited thereto, and the number of the process regions O-VA defined in the open sheet OS may be n rows×m columns (wherein n and m are natural numbers), but is not limited to any one embodiment.

According to an embodiment, a first number of adsorption holes O-H overlapping each of the first portions P1 and P2 of the mask MS may be different from a second number of adsorption holes O-H overlapping each of the second portions Q1 and Q2. For example, the first number may be greater than the second number.

Referring to FIG. 4, the adsorption holes O-H overlapping the first portions P1 and P2 of the mask MS may be spaced apart from each other and arranged along the first direction DR1. The adsorption holes O-H overlapping the second portions Q1 and Q2 may be spaced apart from each other and arranged along the second direction DR2. Adsorption holes O-H may surround a corresponding sheet opening O-OP. The adsorption holes O-H may be more adjacent to the corresponding sheet opening O-OP among the sheet openings O-OP than the welding protrusions WM illustrated in FIG. 2.

According to an embodiment, in plan view, the adsorption holes O-H may each have a shape of a circle, an oval, or a quadrangle. According to the disclosure, the adsorption holes O-H may each be a hole in which a descending airflow is formed such that the adhesive force between the mask MS and the open sheet OS is increased during a coupling process between the mask MS and the open sheet OS. A detailed description thereof will be given through a method for manufacturing a mask assembly.

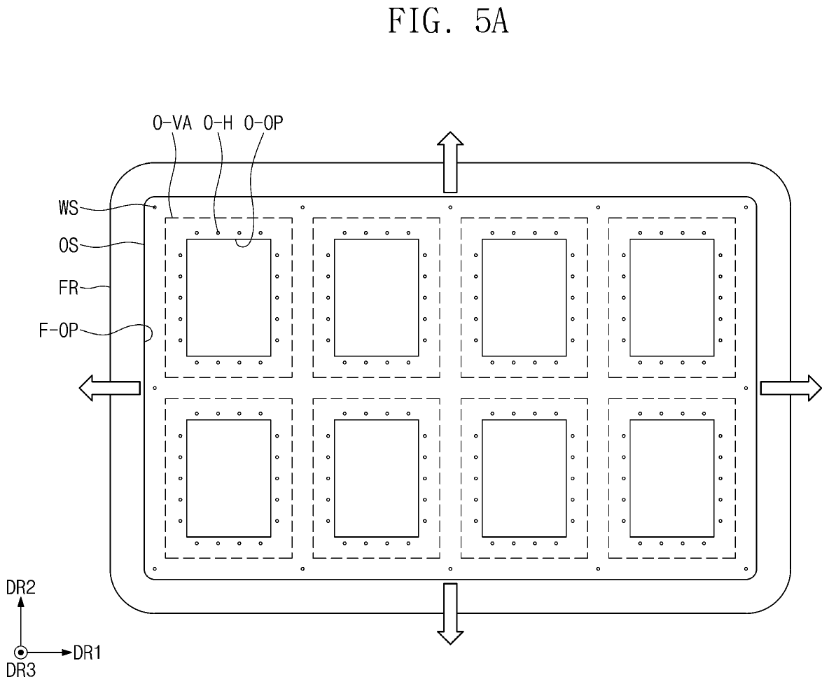

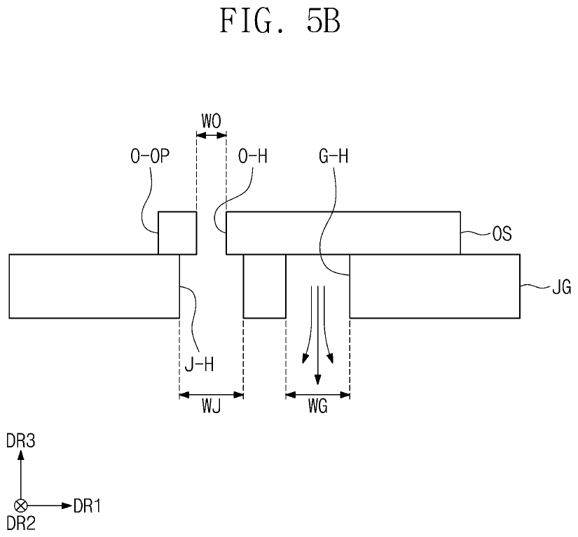

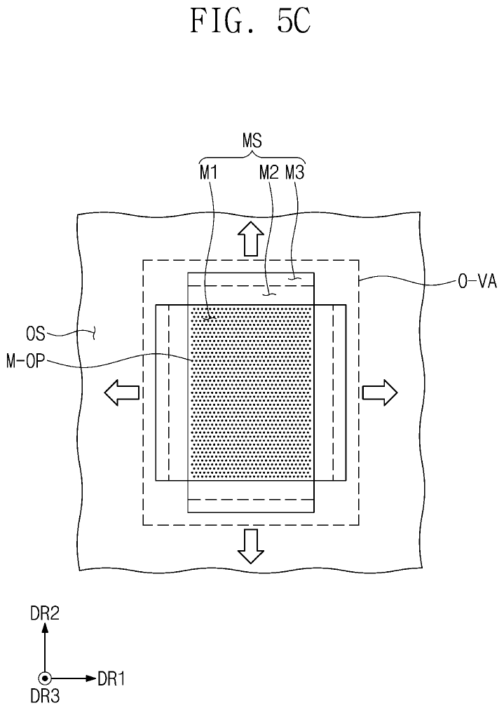

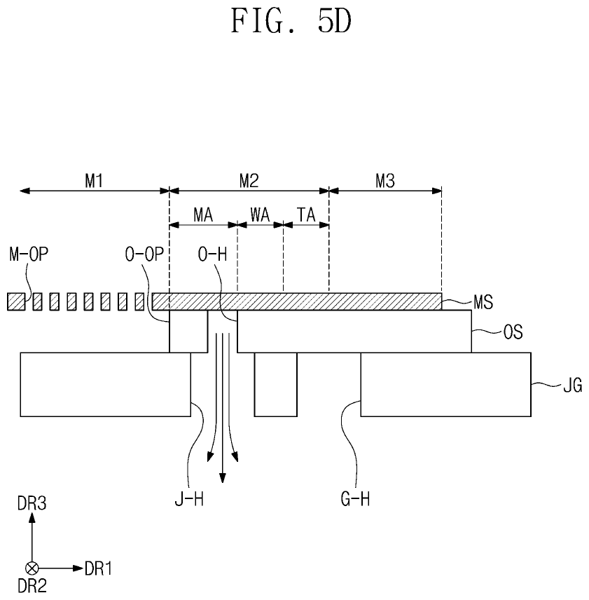

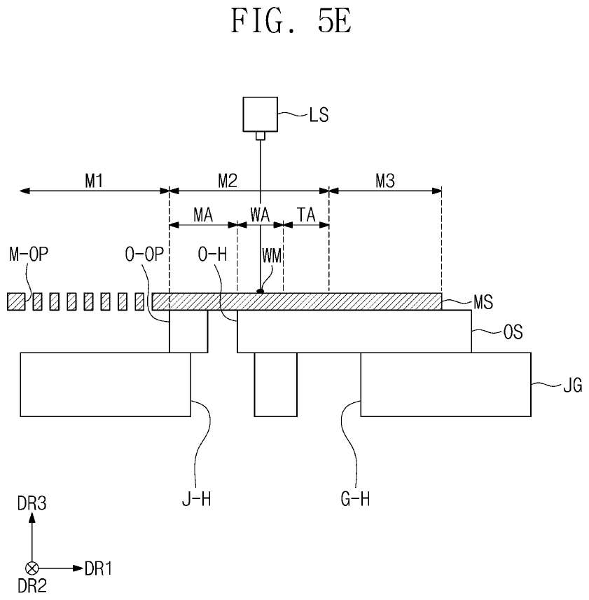

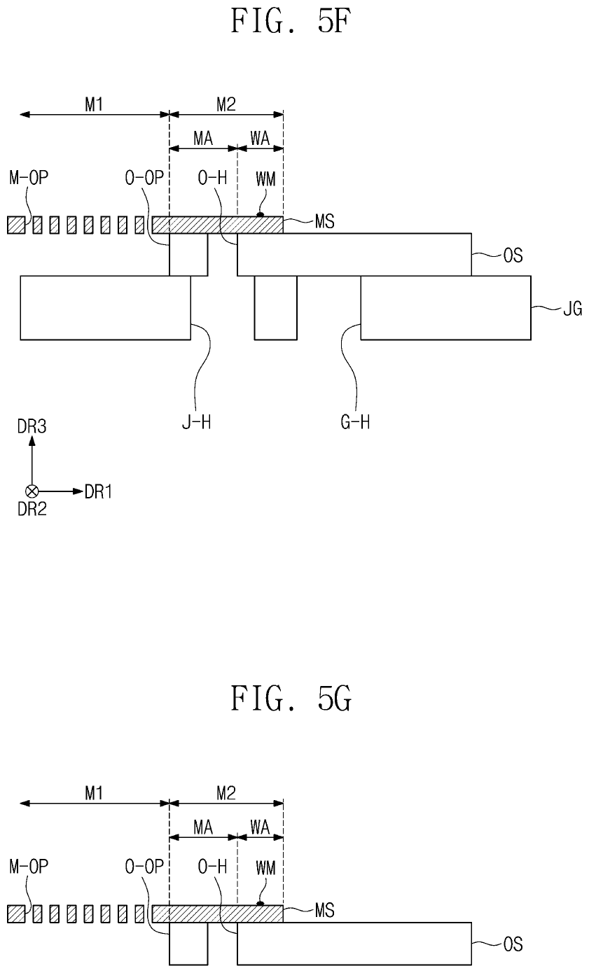

FIG. 5A is a schematic plan view of a method for manufacturing a mask assembly according to an embodiment of the disclosure. FIG. 5B is a schematic cross-sectional view of a method for manufacturing a mask assembly according to an embodiment of the disclosure. FIG. 5C is a schematic plan view of a method for manufacturing a mask assembly according to an embodiment of the disclosure. FIG. 5D is a schematic cross-sectional view of a method for manufacturing a mask assembly according to an embodiment of the disclosure. FIG. 5E is a schematic cross-sectional view of a method for manufacturing a mask assembly according to an embodiment of the disclosure. FIG. 5F is a schematic cross-sectional view of a method for manufacturing a mask assembly according to an embodiment of the disclosure. FIG. 5G is a schematic cross-sectional view of a method for manufacturing a mask assembly according to an embodiment of the disclosure.

Referring to FIG. 5A, the method may include an operation of coupling an open sheet OS to a frame FR.

The frame FR may include a frame opening F-OP, and the open sheet OS may include open sheets O-OP corresponding to the frame opening F-OP and a hole group including adsorption holes O-H surrounding a corresponding open sheet OS among the open sheets OS.

The operation of coupling the open sheet OS to the frame FR may include an operation of stretching the open sheets OS and an operation of welding the open sheets OS and the frame FR.

The operation of stretching the open sheets OS may align the frame opening F-OP and the sheet openings O-OP while stretching, with a structure such as a clamp, the short sides extended in the first direction DR1 of the open sheet OS and the long sides extended in the second direction DR2 thereof.

The operation of welding the open sheets OS and the frame FR may be performed on the open sheets OS while the frame opening F-OP and the sheet openings O-OP are aligned. Therefore, welding protrusions WO may be formed on an upper surface of the open sheet OS overlapped by the frame FR.

Thereafter, referring to FIG. 5B, the method may further include an operation in which a work jig JG and the open sheet OS are disposed and an operation in which the work jig JG and the open sheet OS are brought in close contact with each other.

The work jig JG may be disposed inside the frame opening F-OP while the open sheets OS and the frame FR are coupled. The work jig JG may include first vacuum holes G-H and second vacuum holes J-H in which an airflow is formed. The work jig JG may further include pipes connected to each of the first vacuum holes G-H and the second vacuum holes J-H, a valve connected to the pipes and controlling the opening and closing of the airflow, and a motor forming the airflow. In the first vacuum holes G-H and the second vacuum holes J-H, a descending airflow may be formed through the motor.

In plan view, the first vacuum holes G-H may be more spaced from the sheet opening O-OP than the adsorption holes O-H. The first vacuum holes G-H may be provided as multiple first vacuum holes so as to surround the process region O-VA, or may be provided as one hole so as to overlap each of the short sides and the long sides which define the process region O-VA.

Each of the second vacuum holes J-H may overlap a corresponding adsorption hole O-H among the adsorption holes O-H in plan view, and may be adjacent to the sheet opening O-OP than the first vacuum holes G-H in plan view.

According to an embodiment, a first width WG of each of the first vacuum holes G-H in the first direction DR1 may be greater than a second width WJ of each of the second vacuum holes J-H in the first direction DR1. For example, the first width WG may be approximately 1 mm to approximately 3 mm, and the second width WJ may be greater than a third width WS of a corresponding adsorption hole O-H in the first direction DR2 to approximately 1 mm or less.

The third width WO of each of the adsorption holes O-H in the first direction DR1 may be approximately 50 um to approximately 300 um.

In an operation in which the work jig JG and the open sheet OS are disposed, the open sheets OS may be disposed on the work jig JG such that the second vacuum holes J-H and the adsorption holes O-H are aligned. Therefore, in the operation in which the work jig JG and the open sheets OS are brought in close contact with each other, a descending airflow may be formed in the first vacuum holes G-H. Due to the descending airflow formed in the first vacuum holes G-H, the open sheets OS may be brought in close contact with the work jig JG.

Thereafter, referring to FIG. 5C, the method may include an operation of disposing the masks MS on the open sheets OS.

In the method for manufacturing a mask assembly, an initial mask MS may include a first region M1 having multiple deposition openings M-OP, second regions M2 protruding from short sides and long sides of the first region M1, and third regions M3 extended from a corresponding second region M2 among the second regions M2. Descriptions of each of the second regions M2 and the third regions M3 will be replaced with descriptions of one second region M2 and one third region M3.

The method may further include an operation in which the sheet opening O-OP and the deposition openings M-OP are aligned while the third region M3 of the mask MS is stretched with a clamp or the like. According to an embodiment, the operation of disposing the mask MS on the open sheet OS may be simultaneously performed with the operation of stretching the third region M3 to align the sheet opening O-OP and the deposition openings M-OP.

Thereafter, referring to FIG. 5D, the method may include an operation of bringing the open sheet OS and the mask MS in close contact with each other.

The second region M2 of the mask MS according to an embodiment may include a margin region MA, a welding region WA, and a trimming region TA, which may be arranged in the order of being adjacent to the deposition openings M-OP. The margin region MA may overlap the adsorption holes O-H.

In the operation of bringing the open sheet OS and the mask MS in contact with each other, a descending airflow may be formed in the second vacuum holes J-H. In case that the descending airflow is formed in the second descending airflow J-H, a descending airflow may also be formed in adsorption holes O-H overlapping the second vacuum holes J-H.

Due to the descending airflow formed in the second vacuum holes J-H and the adsorption holes O-H, the mask MS may be brought in close contact with the open sheet OS.

Thereafter, referring to FIG. 5E and FIG. 5G, the method may further include an operation of coupling the masks MS to the open sheets OS and an operation of removing the trimming region TA and the third region M3.

The operation of coupling the masks MS to the open sheets OS may be performed by a welding process in the welding region WA of the mask MS using a welder WE. The welding protrusions WM may be formed on the welding region WA of the mask MS by the welding process. In case that the welding process is performed, the descending airflow may be continuously formed in the second vacuum holes J-H and the adsorption holes O-H.

According to the method for manufacturing a mask assembly according to the disclosure, before or during the operation of coupling the mask MS to the open sheet OS, the descending airflow may be formed in the second vacuum holes J-H and the adsorption holes O-H, so that the adhesive force between the mask MS and the open sheet OS may be increased. Accordingly, the alignment of the sheet opening O-OP of the open sheet OS and the deposition openings M-OP of the mask MS may be improved. Therefore, a mask assembly having improved deposition precision may be provided. In addition, a separate structure for coupling the mask MS to the open sheet OS may be omitted, and a process of manufacturing a mask assembly may be simplified.

Thereafter, the operation of removing the trimming region TA and the third region M3 may be performed by irradiating a laser beam to the trimming region TA of the mask MS using a laser irradiator LS. Accordingly, the completed mask assembly MSA (see FIG. 3) may include only the margin region MA and the welding region WA of the first region M1 and the second region M2.

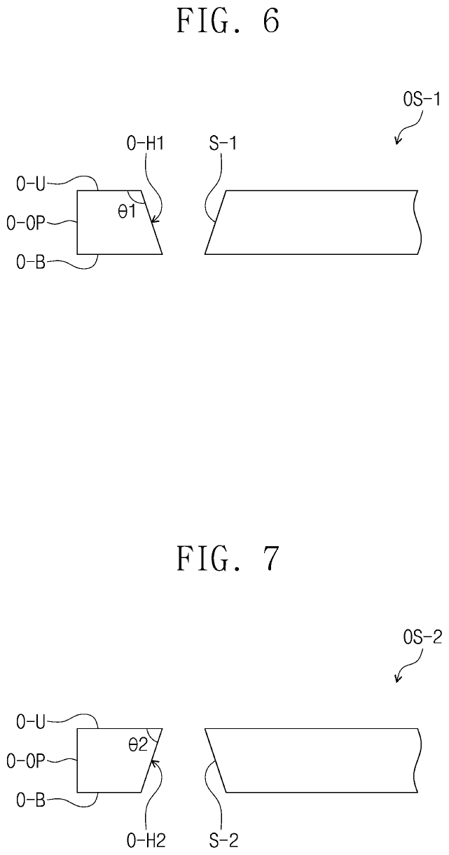

FIG. 6 is a schematic cross-sectional view of an open sheet according to an embodiment of the disclosure. FIG. 7 is a schematic cross-sectional view of an open sheet according to an embodiment of the disclosure. The same/similar reference numerals are used for the same/similar components as those described with reference to FIG. 1 to FIG. 4, and redundant descriptions thereof are omitted.

Referring to FIG. 6, an open sheet OS-1 according to an embodiment may include a sheet opening O-OP and an adsorption hole O-H1.

The open sheet OS-1 may include an upper surface O-U facing the mask MS (see FIG. 3), a rear surface O-B opposing the upper surface O-U, and an inner surface S-1 disposed between the upper surface O-U and the rear surface O-B, and defining the adsorption hole O-H1. According to an embodiment, a first angle Θ1 between the upper surface O-U and the inner surface S-1 may be an obtuse angle. Accordingly, the angle between the rear surface O-B and the inner surface S-1 may be an acute angle. On a cross-section, the shape of the adsorption hole O-H1 may be a reverse tapered shape.

Referring to FIG. 7, an open sheet OS-2 according to an embodiment may include a sheet opening O-OP and an adsorption hole O-H2.

The open sheet OS-2 may include an upper surface O-U facing the mask MS (see FIG. 3), a rear surface O-B opposing the upper surface O-U, and an inner surface S-2 disposed between the upper surface O-U and the rear surface O-B, and defining the adsorption hole O-H2. According to an embodiment, a second angle Θ2 between the upper surface O-U and the inner surface S-2 may be an acute angle. Accordingly, the angle between the rear surface O-B and the inner surface S-2 may be an obtuse angle. On a cross-section, the shape of the adsorption hole O-H2 may be a tapered shape.

However, the angle between an inner surface and an upper surface defining an adsorption hole may be a right angle, but is not limited to any one embodiment.

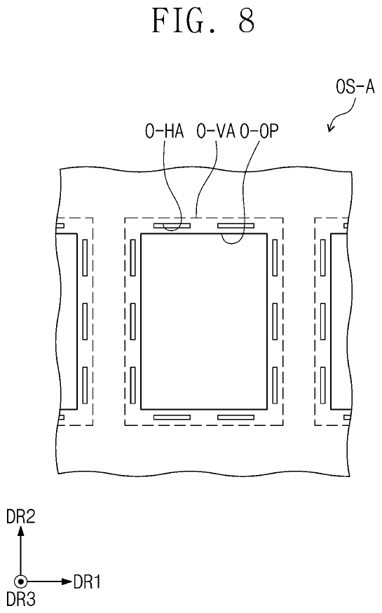

FIG. 8 is a schematic plan view of an open sheet according to an embodiment of the disclosure. The same/similar reference numerals are used for the same/similar components as those described with reference to FIG. 1 to FIG. 4, and redundant descriptions thereof are omitted.

Referring to FIG. 8, an open sheet OS-A according to an embodiment may include sheet openings O-OP and adsorption holes O-HA surrounding a corresponding sheet opening O-OP among the sheet openings O-OP.

The adsorption holes O-HA according to an embodiment may be extended in the same direction as the direction in which an inner surface defining a corresponding sheet opening O-OP is extended, and may be spaced apart from each other. For example, the adsorption holes O-HA, each of which is adjacent to inner surfaces extended along the first direction DR1, may each be extended in the first direction DR1, and may be spaced apart from each other along the first direction DR1. The adsorption holes O-HA, each of which is adjacent to inner surfaces extended along the second direction DR2, may each be extended in the second direction DR2, and may be spaced apart from each other along the second direction DR2.

FIG. 8 illustrates that the adsorption holes O-HA have rectangular shapes in plan view, but the disclosure is not limited thereto, and each of the adsorption holes O-HA may have an elliptical shape in plan view, but is not limited to any one embodiment.

FIG. 9 is a schematic cross-sectional view of a display panel according to an embodiment of the disclosure.

Any one of multiple layers of a display panel DP to be described with reference to FIG. 9 may correspond to a layer formed on the deposition substrate BS through the deposition apparatus EA (see FIG. 1) described with reference to FIG. 1 to FIG. 4.

The display panel DP formed through the deposition apparatus EA of the disclosure may be an organic electroluminescence display panel including an organic electroluminescence element.

The display panel DP may include a display substrate BL and an encapsulation substrate US. The display substrate BL may include a first base layer BS1, a circuit element layer DP-CL disposed on the first base layer BS1, a display element layer DP-OLED disposed on the circuit element layer DP-CL, and a cover layer CV disposed on the display element layer DP-OLED. The encapsulation substrate US may include a second base layer BS2, a black matrix layer BML disposed on the second base layer BS2, and a control layer CCL.

The first base layer BS1 may include a synthetic resin film. In addition, the first base layer BS1 may include a glass substrate, a metal substrate, an organic/inorganic composite material substrate, and/or the like.

The circuit element layer DP-CL is disposed on the first base layer BS1. The circuit element layer DP-CL may include insulation layers, a semiconductor pattern, a conductive pattern, a signal line, and/or the like. An insulation layer, a semiconductor layer, and/or a conductive layer may be formed by coating, deposition, and the like. Thereafter, the insulation layer, the semiconductor layer, and/or the conductive layer may be selectively patterned by photolithography.

The semiconductor pattern, the conductive pattern, the signal line, and/or the like included in circuit element layer DP-CL and the display element layer DP-OLED may be formed in the above manner. At least one of the insulation layers and the conductive patterns which may be included in the circuit element layer DP-CL may be formed through the deposition apparatus EA according to the disclosure. Therefore, the deposition substrate BS of FIG. 1 may correspond to the first base layer BS1.

The display element layer DP-OLED may include a light emitting element OLED and a pixel definition film PDL. On the pixel definition film PDL, a display opening OP may be defined. For example, the pixel definition film PDL may be an organic layer. The light emitting element OLED may include a first electrode AE, a hole control layer HCL, a light emitting layer EML, an electron control layer ECL, and a second electrode CE.

The display panel DP may include a light emitting region PXA and a non-light emitting region NPXA adjacent to the light emitting region PXA. The light emitting region PXA may be defined to correspond to a region of the first electrode AE exposed by the display opening OP. The light emitting layer EML according to an embodiment may be formed by the deposition apparatus EA according to the disclosure. Therefore, the light emitting layer EML may be individually deposited for each light emitting region PXA.

The hole control layer HCL may be commonly disposed in the light emitting region PXA and the non-light emitting region NPXA. The hole control layer HCL may include a hole transport layer, and may further include a hole injection layer. On the hole control layer HCL, the light emitting layer EML may be disposed. The light emitting layer EML may be disposed in a region corresponding to the display opening OP.

On the light emitting layer EML, the electron control layer ECL may be disposed. The electron control layer ECL may include an electron transport layer, and may further include an electron injection layer. On the electron control layer ECL, the second electrode CE may be disposed.

On the second electrode CE, a cover layer CV may be disposed. The cover layer CV may include multiple thin films. As in an embodiment, the cover layer CV may include either a capping layer or a thin film encapsulation layer.

A second base layer BS2 may be disposed spaced apart from the cover layer CV. The second base layer BS2 may be at least one among a glass substrate, a plastic substrate, and a substrate containing polyimide (PI).

Depending on the color of light provided by the light emitting element OLED, a color control layer CCL may transmit a first color light, or may convert the first color light into a second color light or a third color light. The color control layer CCL may include a quantum dot. For example, the first color light may be blue light.

A black matrix layer BML may overlap the non-light emitting region NPXA. The black matrix layer BML may have a black color. The black matrix layer BML may include a material which absorbs light, and is not limited to any one embodiment.

According to a method for manufacturing a mask assembly according to the disclosure, a descending airflow may be formed in vacuum holes of a work jig and adsorption holes of an open sheet, so that the adhesive force between a mask and the open sheet may be increased. Accordingly, the alignment of a sheet opening of the open sheet and deposition openings of the mask may be improved. Therefore, a mask assembly having improved deposition precision may be provided.

In addition, a separate structure for coupling the mask to the open sheet may be omitted, and a process of manufacturing a mask assembly may be simplified.

Although the disclosure has been described with reference to embodiments, it will be understood by those skilled in the art that various modifications and changes in form and details may be made therein without departing from the spirit and scope of the disclosure.

Accordingly, the technical scope of the disclosure is not intended to be limited to the contents set forth in the detailed description of the specification.

What is claimed is:

1. A mask assembly comprising:
a frame including a frame opening;
an open sheet physically connected to the frame and including:
sheet openings corresponding to the frame opening; and
hole groups each of which includes adsorption holes spaced apart from a corresponding sheet opening among the sheet openings; and
masks each of which includes deposition openings, and is physically connected to the open sheet so as to be aligned with a corresponding sheet opening among the sheet openings,
wherein each of the masks overlaps the adsorption holes of a corresponding hole group among the hole groups.

2. The mask assembly of claim 1, wherein
each of the masks comprises:
a first region in which the deposition openings are defined; and
a second region protruding from the first region in plan view and overlapping the adsorption holes of a corresponding hole group,
wherein the mask assembly further comprises welding protrusions disposed on an upper surface of the second region of each of the masks.

3. The mask assembly of claim 2, wherein in plan view, the adsorption holes are more adjacent to a corresponding sheet opening among the sheet openings than the welding protrusions.

4. The mask assembly of claim 2, wherein
the first region of each of the masks comprises:
short sides each of which is extended in a first direction and spaced apart in a second direction intersecting the first direction; and
long sides each of which is extended in the second direction, spaced apart in the first direction, and extended to the short sides, and
the second region of each of the masks comprises first portions protruding from the short sides and second portions protruding from the long sides.

5. The mask assembly of claim 4, wherein among the adsorption holes, a number of adsorption holes overlapping each of the first portions and a number of adsorption holes overlapping each of the second portions are different from each other.

6. The mask assembly of claim 4, wherein
each of the adsorption holes has a shape of at least one of a circle, an oval, and a quadrangle,
among the adsorption holes, adsorption holes overlapping the first portions are arranged in the first direction, and
among the adsorption holes, adsorption holes overlapping the second portions are arranged in the second direction.

7. The mask assembly of claim 4, wherein:
among the adsorption holes, each of adsorption holes overlapping the first portions are extended in the first direction and arranged in the first direction; and
among the adsorption holes, each of adsorption holes overlapping the second portions are extended in the second direction and arranged in the first direction.

8. The mask assembly of claim 1, wherein the open sheet comprises:
an upper surface facing the masks;
a lower surface opposing the upper surface; and
an inner surface extending between the upper surface and the lower surface and defining the adsorption holes,
wherein an angle between the upper surface and the inner surface and the angle between the lower surface and the inner surface are right angles.

9. The mask assembly of claim 1, wherein the open sheet comprises:
an upper surface facing the masks;
a lower surface opposing the upper surface; and
an inner surface extending between the upper surface and the lower surface and defining the adsorption holes, and
an angle between the upper surface and the inner surface or the angle between the lower surface and the inner surface are obtuse angles.

10. The mask assembly of claim 1, wherein a width of each of the adsorption holes is about 50 um to about 300 um.

11. The mask assembly of claim 1, wherein the mask assembly further comprises:
welding protrusions overlapping the frame and disposed on an upper surface of the open sheet.

12. The mask assembly of claim 1, wherein at least one of the frame, the open sheet, and the masks comprises invar.

13. The mask assembly of claim 1, wherein:
a thickness of the open sheet is about 50 um to about 300 um; and
a thickness of each of the masks is about 10 um to about 50 um.

14. A deposition apparatus comprising:
a chamber;
a mask assembly disposed inside the chamber and including a deposition substrate; and
a deposition source spraying a deposition material toward the mask assembly, wherein the mask assembly includes:
a frame including a frame opening;
an open sheet physically connected to the frame and including:
sheet openings corresponding to the frame opening, and
hole groups each of which includes adsorption holes spaced apart from a corresponding sheet opening among the sheet openings; and
masks each of which includes deposition openings, and is physically connected to the open sheet so as to be aligned with a corresponding sheet opening among the sheet openings, and
each of the masks overlaps the adsorption holes of a corresponding hole group among the hole groups.

15. A method for manufacturing a mask assembly, the method comprising:
coupling an open sheet on which a sheet opening and adsorption holes spaced apart from the sheet opening are formed to a frame;
disposing the open sheet on a work jig in which first vacuum holes and second vacuum holes spaced apart from the first vacuum holes are defined such that the adsorption holes and the second vacuum holes are aligned;
forming a descending airflow in the first vacuum holes to bring the open sheet in close physical contact with the work jig;
disposing a mask in which deposition openings corresponding to the sheet opening are defined on the open sheet;
forming a descending airflow in the adsorption holes and the second vacuum holes to bring the mask in close physical contact with the open sheet; and
coupling the mask to the open sheet.

16. The method of claim 15, wherein
the mask comprises:
a first region in which the deposition openings are defined;
a second region protruding from the first region; and
a third region protruding from the second region, and
the second region includes a margin region, a welding region, and a trimming region arranged in an order adjacent to the deposition openings and overlapping the adsorption holes, and
the method further comprises stretching the third region to align the sheet opening and the deposition openings.

17. The method of claim 16, wherein the stretching of the third region to align the sheet opening and the deposition openings and the disposing of a mask on the open sheet are simultaneously performed.

18. The method of claim 17, wherein the coupling of the mask to the open sheet is performed by a welding process to the welding region.

19. The method of claim 18, further comprising:
after the coupling of the mask to the open sheet, removing the trimming region and the third region by irradiating a laser beam to the trimming region.

20. The method of claim 16, wherein a width of the adsorption holes in a direction is smaller than a width of the second vacuum holes in the direction. SD-220948-ROB 5
